(19) United States
(12) Patent Application Publication
(10) Pub. No.: US 2011/0104879 A1
(43) Pub. Date: May 5, 2011

(54) METHOD OF MANUFACTURING SEMICONDUCTOR DEVICE AND SUBSTRATE PROCESSING APPARATUS

(75) Inventor: Takeo HANASHIMA, Toyama-shi (JP)

(73) Assignee: HITACHI-KOKUSAI ELECTRIC INC., Tokyo (JP)

(21) Appl. No.: 12/897,037

(22) Filed: Oct. 4, 2010

(30) Foreign Application Priority Data
Oct. 30, 2009 (JP) 2009-249628
Jun. 28, 2010 (JP) 2010-146008

(51) Int. Cl. H01L 21/20; C23C 16/30; B05C 11/10

(52) U.S. Cl. 438/482; 118/715; 118/696; 257/E21.09

(57) ABSTRACT

Provided are a method of manufacturing a semiconductor device and a substrate processing apparatus, which can improve the surface roughness of an amorphous silicon film. The method of manufacturing a semiconductor device comprises: in a process of forming an amorphous silicon film on a substrate, setting, in an initial stage of the process, an in-furnace pressure to a first pressure to supply SiH₄; and setting, in a stage after the initial stage, the in-furnace pressure to a second pressure lower than the first pressure to supply SiH₄.

### CROSS-REFERENCE TO RELATED PATENT APPLICATION

This U.S. non-provisional patent application claims priority under 35 U.S.C. §119 of Japanese Patent Application Nos. 2009-249628, filed on Oct. 30, 2009, and 2010-146008, filed on Jun. 28, 2010, in the Japanese Patent Office, the entire contents of which are hereby incorporated by reference.

### BACKGROUND OF THE INVENTION

1. Field of the Invention

The present invention relates to a method of manufacturing a semiconductor device, and more particularly, to a method of manufacturing a semiconductor device and a substrate processing apparatus, which are configured to form an amorphous silicon film.

2. Description of the Related Art

In a process of manufacturing semiconductor devices such as integrated circuits (ICs) and large scale integrated circuits (LSIs), a depressurization chemical vapor deposition (CVD) method is used to form a thin film on a substrate.

When an amorphous silicon film (hereinafter, referred to as an a-Si film) is deposited on an insulating film, SiH₄ (monosilane) gas is used as source gas in a temperature range that is equal to or less than a film forming temperature ranging from 480° C. to 550° C. As semiconductors are miniaturized, it is required to improve the surface roughness of an a-Si film, that is, a film having a smoother surface is required. In Patent Document 1 below, a technology for improving the surface roughness of a poly-SiGe film is disclosed.

FIG. 5 is a graph illustrating variations in the flow rate of SiH₄ and an in-furnace pressure in a film forming sequence in the related art. A pre-purge event (hereinafter, referred to as a pre-purge process), which is an initial stage in forming a film, is used to stabilize SiH₄ gas at a prescribed flow rate. The flow rate of SiH₄ gas shown in the current example is increased for about 15 seconds from 0 SLM to 0.8 SLM that is a prescribed value, and the in-furnace pressure is increased also for 15 seconds up to about 15 Pa. In a DEPO event (hereinafter, referred to as a DEPO process), which is a process after the initial stage in forming a film, a process condition including a pressure and a gas flow rate is determined according to a forming device, and is basically a fixed condition. The flow rate of SiH₄ gas shown in the current example is constantly maintained at 0.8 SLM, and the in-furnace pressure is increased for about 15 seconds from about 15 Pa to 40 Pa. From results of the above-described film forming sequence in the related art, the surface state result of an a-Si film is shown in a sequence (a) of FIG. 4, in which the a-Si film had a surface level of 6.8 and the number of particles was over a detection upper limit, and thus, it is required to improve the surface roughness of the a-Si film.

[Patent Document 1]
Japanese Unexamined Patent Application Publication No. 2009-147388

### SUMMARY OF THE INVENTION

An object of the present invention is to provide a method of manufacturing a semiconductor device and a substrate processing apparatus, which can solve the above-described problems of the related art and improve the surface roughness of an a-Si film.

According to an aspect of the present invention, there is provided a method of manufacturing a semiconductor device, the method comprising: in a process of forming an amorphous silicon film on a substrate, setting, in an initial stage of the process, an in-furnace pressure to a first pressure to supply SiH4; and setting, in a stage after the initial stage, the in-furnace pressure to a second pressure lower than the first pressure to supply SiH4.

According to another aspect of the present invention, there is provided a method of manufacturing a semiconductor device, the method comprising: in a process of forming an amorphous silicon film on a substrate, supplying, in an initial stage of the process, SiH4 at a first flow rate; and supplying, in a stage after the initial stage, SiH4 at a second flow rate greater than the first flow rate.

According to another aspect of the present invention, there is provided a method of manufacturing a semiconductor device, the method comprising: in a process of forming an amorphous silicon film on a substrate, setting, in an initial stage of the process, an in-furnace pressure to a first pressure to supply SiH4 at a first flow rate; and setting, in a stage after the initial stage, the in-furnace pressure to a second pressure lower than the first pressure to supply SiH4 at a second flow rate greater than the first flow rate.

According to another aspect of the present invention, there is provided a substrate processing apparatus comprising: a process furnace; a monosilane gas supply part configured to supply monosilane gas; a pressure control part configured to control pressure; and a controller control part configured to control the monosilane gas supply part to supply the monosilane gas and form an amorphous silicon film at a first pressure in an initial stage of a process of forming the amorphous silicon film on a substrate, the controller control part being configured to control the monosilane gas supply part to form the amorphous silicon film at a second pressure higher than the first pressure after the initial stage, the controller control part being configured to control the pressure control part such that the second pressure is less than the first pressure in the initial stage.

According to another aspect of the present invention, there is provided a substrate processing apparatus comprising: a process furnace; a monosilane gas supply part configured to supply monosilane gas; a pressure control part configured to control pressure; and a controller control part configured to control the monosilane gas supply part to supply the monosilane gas and supply the monosilane gas at a first flow rate in an initial stage of a process of forming an amorphous silicon film on a substrate, the controller control part being configured to control the monosilane gas supply part to supply the monosilane gas at a second flow rate greater than the first flow rate after the initial stage.

### BRIEF DESCRIPTION OF THE DRAWINGS

FIG. 1 is a perspective view illustrating a substrate processing apparatus according to an embodiment of the present invention.

FIG. 2 is a schematic view illustrating a structure of a reaction furnace of a vertical depressurization CVD apparatus according to an embodiment of the present invention.

FIG. 3 is a block diagram illustrating the film forming order of a depressurization CVD method according to an embodiment of the present invention.

FIG. 4 is a table illustrating evaluation results of a sequence of the present invention and a related art sequence.

FIG. 5 is a graph illustrating variations in the flow rate of SiH₄ and pressure when a related art a-Si film is formed.

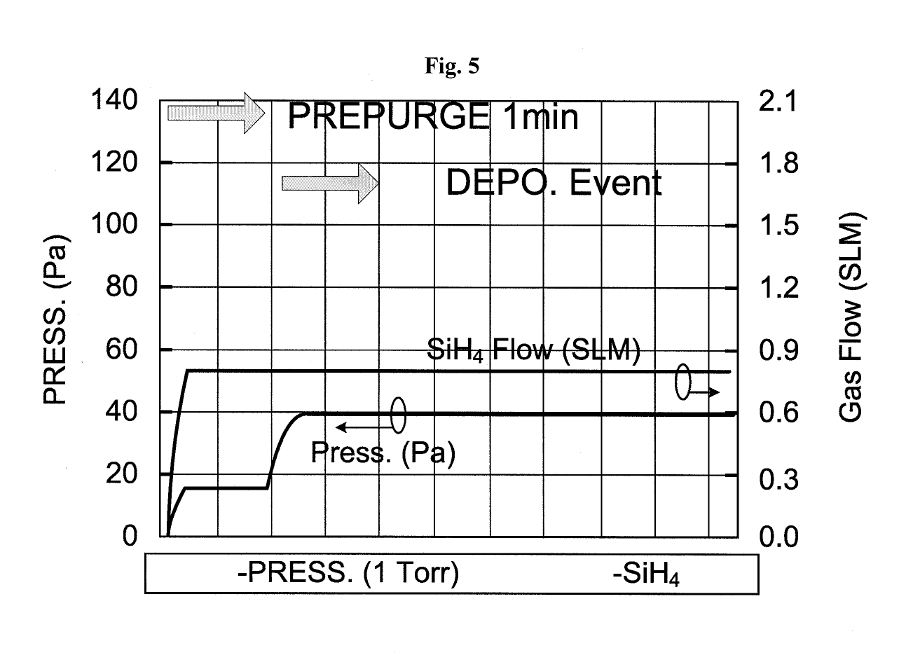

FIG. 6 is a graph illustrating variations in the flow rate of SiH₄ and pressure when an a-Si film is formed according to a first embodiment of the present invention.

FIG. 7 is a graph illustrating variations in the flow rate of SiH₄ and pressure when an a-Si film is formed according to a second embodiment of the present invention.

### DETAILED DESCRIPTION OF THE PREFERRED EMBODIMENTS

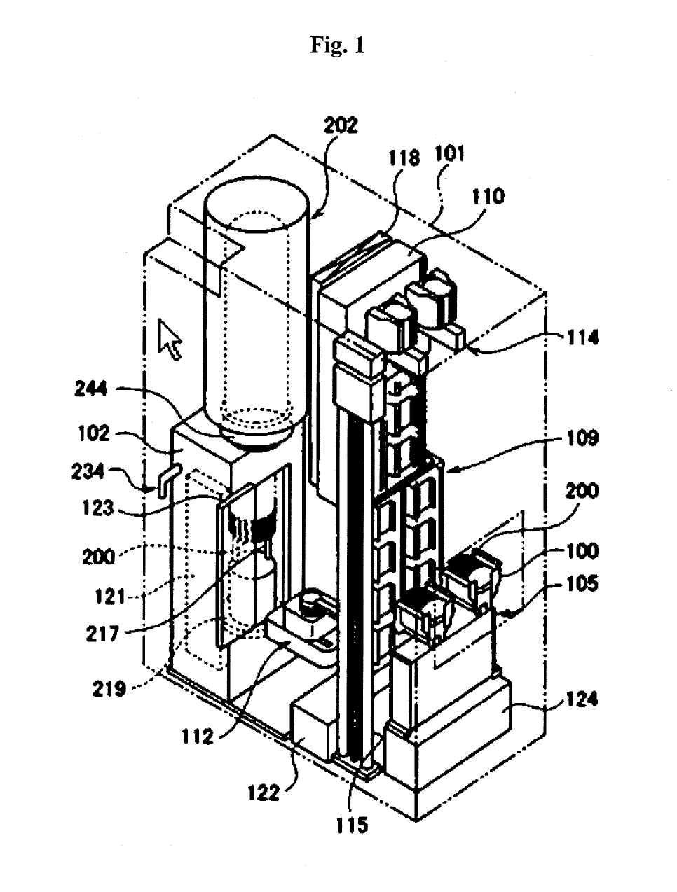

Hereinafter, a method of manufacturing a semiconductor device will be described according to embodiments of the present invention. First, referring to FIG. 1, a substrate processing apparatus for performing a method of manufacturing a semiconductor device will now be schematically described according to an embodiment of the present invention.

At the front surface side in a housing 101, the cassette stage 105 is installed as a holder delivery member such that cassettes 100 as substrate containers are delivered between the cassette stage 105 and an external carrying device (not shown), and a cassette elevator 115 is installed as an elevating unit at the rear side of the cassette stage 105, and the cassette elevator 115 is provided with a cassette transfer device 114 installed as a carrying unit. At the rear side of the cassette elevator 115, a cassette shelf 109 is installed as a placement unit for the cassette 100, and is installed such that the cassette shelf 109 can laterally move above a slide stage 122. In addition, at the upper side of the cassette shelf 109, a buffer cassette shelf 110 is installed as a placement unit for the cassette 100. At the rear side of the buffer cassette shelf 110, a cleaning unit 118 is installed to circulate clean air through the inside of the housing 101.

At the rear upper side of the housing 101, a process furnace 202 is installed, and the lower side of the process furnace 202 contacts a load lock chamber 102 as a rectangular air-tight chamber through a gate valve 244 as a partition cover, and the front surface of the load lock chamber 102 is provided with a load lock door 123 installed as a partition unit at a position facing the cassette shelf 109. In the load lock chamber 102, a boat elevator 121 is installed as an elevating unit configured such that a boat 217 as a substrate holding unit configured to hold wafers 200 as substrates to be horizontally oriented and arranged in multiple stages is moved upward to and downward from the process furnace 202, and the boat elevator 121 is provided with a seal cap 219 made of stainless steel and installed as a cover part to vertically support the boat 217. Between the load lock chamber 102 and the cassette shelf 109, a transfer elevator (not shown) is installed as an elevating unit, and the transfer elevator is provided with a wafer transfer device 112 installed as a carrying unit.

Hereinafter, a series of operations of the substrate processing apparatus will now be described. The cassette 100 carried in from the external carrying device (not shown) is placed on the cassette stage 105, and is rotated 90° at the cassette stage 105, and a combination of the elevation operation and lateral movement operation of the cassette elevator 115 and the back-and-forth operation of the cassette transfer device 114 is performed to carry the cassette 100 to the cassette shelf 109 or the buffer cassette stage 110.

The wafer transfer device 112 transfers the wafers 200 from the cassette shelf 109 to the boat 217. As a preparation for transferring the wafers 200, the boat 217 is moved downward by the boat elevator 121, and the gate valve 244 closes the process furnace 202, and purge gas such as nitrogen gas is introduced into the load lock chamber 102 from a purge nozzle 234. The pressure of the load lock chamber 102 is recovered to the atmospheric pressure, and then, the load lock door 123 is opened.

A horizontal slide mechanism as the slide stage 122 horizontally moves the cassette shelf 109, and positions the cassette 100 as a transfer target to correspond to the wafer transfer device 112. The wafer transfer device 112, through a combination of an elevation operation and a rotation operation, transfers the wafers 200 from the cassette 100 to the boat 217. The transfer of the wafers 200 is performed with the several cassettes 100, and the transfer of a predetermined number of the wafers to the boat 217 is completed, and then, the load lock door 123 is closed to vacuum the load lock chamber 102.

After the vacuuming is completed, when gas is introduced from the gas purge nozzle 234 and the inner pressure of the load lock chamber 102 is recovered to the atmospheric pressure, the gate valve 244 is opened, and the boat elevator 121 inserts the boat 217 into the process furnace 202, and the gate valve 244 is closed. After the vacuuming is completed, instead of recovering the inner pressure of the load lock chamber 102 to the atmospheric pressure, the boat 217 may be inserted into the process furnace 202 at a pressure equal to or less than the atmospheric pressure.

A predetermined process is performed on the wafers 200 in the process furnace 202, and then, the gate valve 244 is opened, and the boat elevator 121 unloads the boat 217, and the inner pressure of the load lock chamber 102 is recovered to the atmospheric pressure, and then, the load lock door 123 is opened.

In the reverse sequence to the above-described sequence, the wafers 200 after the process are transferred from the boat 217 through the cassette shelf 109 to the cassette stage 105, and are carried out by the external carrying device (not shown).

A carrying operation of a part such as the cassette transfer device 114 is controlled by a carrying control unit 124.

The method of manufacturing the semiconductor device according to the current embodiment uses a hot wall vertical depressurization chemical vapor deposition (CVD) apparatus as the above-described substrate processing apparatus, and uses monosilane as reaction gas in the process furnace 202 (also referred to as a reaction furnace hereinafter) as a component of the hot wall vertical depressurization CVD apparatus, to form an a-Si film on a wafer.

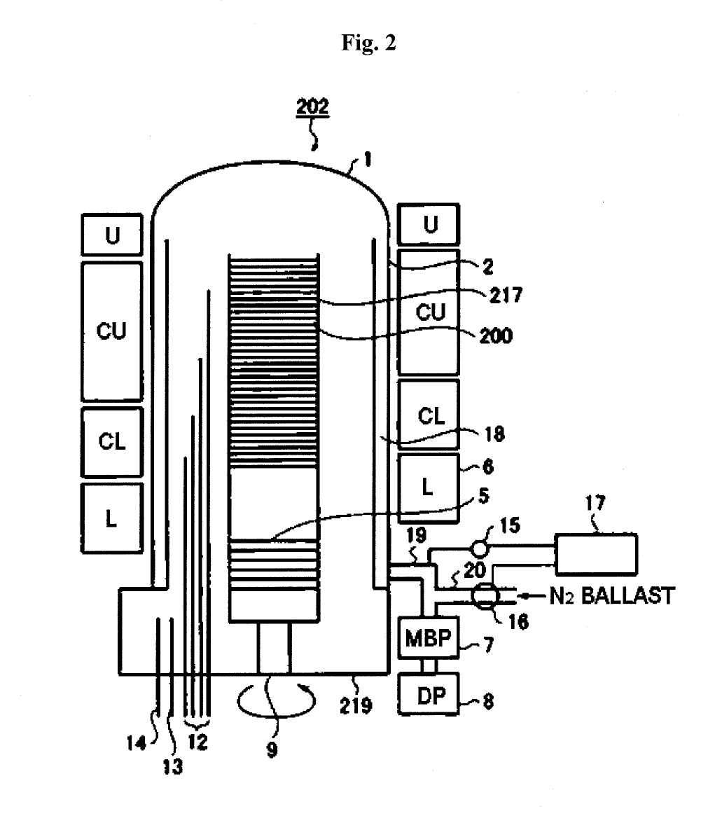

FIG. 2 is a schematic view illustrating a structure of a reaction furnace of a hot wall vertical depressurization CVD apparatus.

At the inside of a hot wall constituted by a heater 6 divided into four zones, an outer tube 1 that is an external cylinder of the process furnace 202 and made of a quartz material, and an inner tube 2 that is disposed in the outer tube 1 are installed.

A bottom opening of the outer tube 1 and the inner tube 2 is sealed by the seal cap 219 that is made of stainless steel. A plurality of gas nozzles 12 pass through the seal cap 219. A plurality of gas supply pipes are constituted by a plurality of SiH₄/N₂ nozzles (also denoted by reference numeral 12) configured to supply monosilane and nitrogen gas. The plurality of gas supply pipes (also denoted by reference numeral 12) supplies process gas into the inner tube 2. In addition, the SiH₄/N₂ nozzles 12 may be constituted by a plurality of nozzle parts that are different in length, and may be referred to as midstream supply nozzles since the SiH₄/N₂ nozzles 12 supply monosilane on the way of the boat 217.

The gas nozzles 12 are connected to a mass flow controller (MFC, not shown) so as to control the flow rate of supplied gas to a predetermined amount.

A cylindrical space 18 formed between the outer tube 1 and the inner tube 2 is connected to an exhaust pipe 19. The exhaust pipe 19 is connected to a mechanical booster pump (MBP) 7 and a dry pump (DP) 8 to discharge gas flowing through the cylindrical space 18 formed between the outer tube 1 and the inner tube 2. In addition, the exhaust pipe 19 is branched at an upstream side of the mechanical booster pump 7, and a branch exhaust pipe 20 formed from the branched exhaust pipe 20 is connected to an N₂ ballast source (not shown) through a valve 16 for an N₂ ballast, and an inner pressure of the exhaust pipe 19 is detected using a pressure gauge 15 to maintain the inside of the outer tube 1 in depressurization atmosphere having a predetermined pressure, and a controller control part 17 controls, based on the value of the detected inner pressure, the valve 16 for an N2 ballast.

In addition, the boat 217 made of a quartz material, charged with a plurality of wafers 200 is installed in the inner tube 2. An insulating plate 5 charged to the lower part of the boat 217 is used for insulating the region between the boat 217 and the lower part of the apparatus. The boat 217 is supported by a rotation shaft 9 that is air-tightly inserted from the seal cap 219. The rotation shaft 9 is configured to rotate the boat 217 and the wafers 200 held on the boat 217, and is controlled by a driving control part (not shown) to rotate the boat 217 at a predetermined speed.

Thus, when an a-Si film is formed, monosilane and nitrogen are respectively introduced from the SiH₄/N₂ nozzles 12 at the inside of the inner tube 2, and reaction gas moves upward through the inside of the inner tube 2, moves downward through the cylindrical space 18 between two types of the tubes 1 and 2, and are exhausted from the exhaust pipe 19. When the boat 217 (with 8 inches and a pitch of 5.2 mm) charged with a plurality of wafers 200 is exposed to reaction gas, through reactions occurring in a gaseous phase and on surfaces of the wafers 200, thin films are formed on the wafers 200.

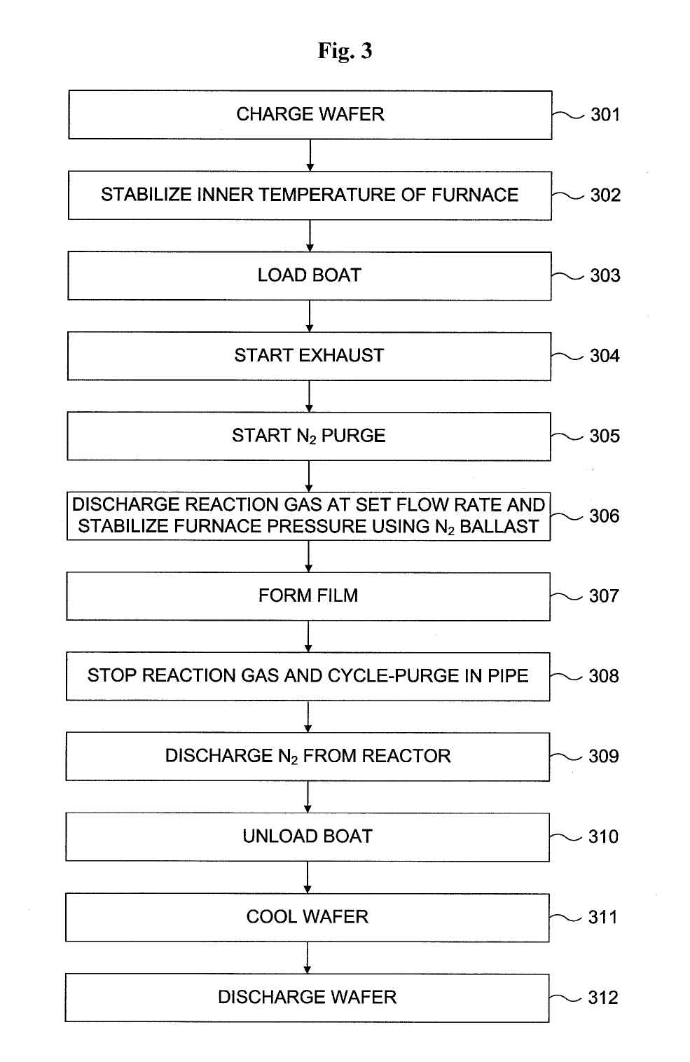

Next, the order of a film forming process using the vertical depressurization CVD apparatus including the above-described reaction furnace is shown in FIG. 3. First, wafers 200 are charged (in step 301), then, the inner pressure of the process furnace 202 is stabilized (PRESS-CONT: pressure control process) to 100 Pa (in step 302), and then, the boat 217 charged with the wafers 200 is loaded into the process furnace 202 (in step 303). The inside of the tubes 1 and 2 is evacuated, and an N₂ purge process is performed to remove materials such as moisture adsorbed to the boat 217 or the tubes 1 and 2 (in step 305). After that, flow rates of monosilane gas and nitrogen gas are set at the MFC (not shown), and a process such as a N₂ ballast control using the controller control part 17 is performed for stabilizing such that each gas is discharged to the process furnace 202 to reach a growth pressure (in step 306). Then, after the growth pressure in the process furnace 202 is stabilized, a predetermined film forming process is performed (in step 307). When the film forming process is ended, the insides of nozzles 12, 13, and 14 are cycle-purged with N₂, and N₂ is used to return the inner pressures of the tubes 1 and 2 to the atmospheric pressure (in step 308 and step 309). When the inner pressures of the tubes 1 and 2 are returned to the atmospheric pressure, the boat 217 is unloaded, and the wafers 200 are naturally cooled (in step 310 and step 311). Finally, the wafers 200 are discharged from the boat 217 (in step 312).

In the method of manufacturing the semiconductor device according to the current embodiment, the process furnace 202 includes the tubes 1 and 2 configured to process the wafers 200, the heater 6 configured to heat the wafers 200 in the tubes 1 and 2, and the SiH₄/N₂ nozzles 12 configured to supply monosilane as reaction gas into the tubes 1 and 2, and supplies only monosilane from the nozzle 13 into the reaction pipe in the above-described predetermined film forming process, and forms a-Si films on wafers.

The film forming process is performed using a depressurization CVD method in which a film forming pressure is controlled by the controller control part 17. When an a-Si film is formed on a wafer, an initial stage (pre-purge process) of a film forming process is different in a film forming pressure value from a stage (DEPO process) after the initial stage, for example, an in-furnace pressure of 100 Pa is applied in the pre-purge process and an in-furnace pressure of 40 Pa is applied in the DEPO process after the pre-purge process. In this way, the surface roughness of an a-Si film can be improved.

### Embodiment

The vertical depressurization CVD apparatus including the reaction furnace shown in FIG. 2 is used to form a-Si films on wafers.

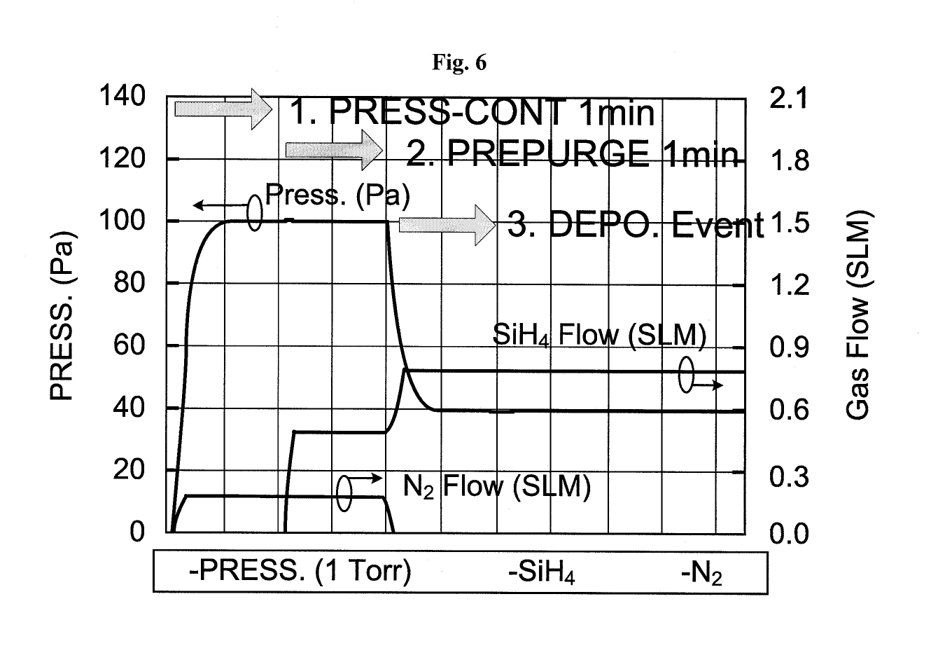

The a-Si films are formed by using the controller control part 17 to control a film farming pressure, the flow rate of SiH₄, and the flow rate of N₂. FIG. 6 is a graph illustrating variations in the flow rate of SiH₄, the flow rate of N₂, and the inner pressure of a reaction furnace according to a first embodiment of the present invention. First, in a pressure control process (PRESS-CONT) denoted by reference numeral 1, when a supply of SiH₄ is started, N₂ is supplied to maintain an in-furnace pressure at a high pressure (100 Pa in this example). The pressure control process is used to stabilize an in-furnace pressure to a high pressure before forming a film. In a pre-purge process (PREPURGE) denoted by reference numeral 2, while the inside of the reaction furnace is maintained at the high pressure (100 Pa), SiH₄ is supplied for about 5 seconds at a constant flow rate of 0.5 SLM that is less than a prescribed flow rate (in this example, 0.8 SLM), and N₂ is supplied at a constant flow rate of 0.2 SLM to stabilize the flow rate. The surface roughness of the a-Si film is determined according to the in-furnace pressure and the flow rate of SiH₄ in this process. That is, as the flow rate of SiH₄ decreases in the pre-purge process that is an initial film forming stage, the surface roughness is improved; and, as pressure increases, the surface roughness is improved. In addition, it is proper that this process has a process time of 1 minute in this example, but the present invention is not limited thereto. In a DEPO process (DEPO) denoted by reference numeral 3, the in-furnace pressure is decreased (in this example, to 40 Pa) for about 30 seconds, and is kept constant, and the flow rate of SiH₄ is increased to the prescribed flow rate of 0.8 SLM for about 10 seconds, and is kept constant. Under this condition, the a-Si film is formed.

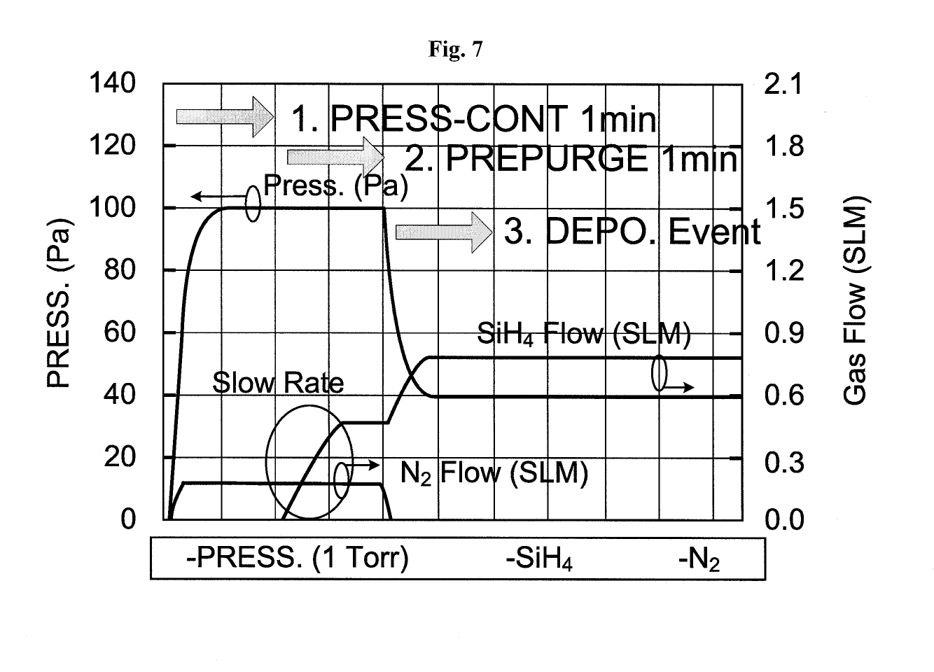

FIG. 7 is a graph illustrating variations in the flow rate of SiH₄, the flow rate of N₂, and the inner pressure of a reaction furnace according to a second embodiment of the present invention. First, in a pressure control process (PRESS-CONT) denoted by reference numeral 1, when a supply of SiH₄ is started, to maintain an in-furnace pressure at a high pressure (100 Pa in this example), N₂ is increased up to 0.2 SLM for about 10 seconds, and then, is supplied constantly. The pressure control process is used to stabilize an in-furnace pressure to a high pressure before forming a film. In a pre-purge process (PREPURGE) denoted by reference numeral 2, while the inside of the reaction furnace is maintained at the high pressure (100 Pa), SiH₄ is slowly increased for about 30 seconds up to a constant flow rate of 0.5 SLM that is less than a prescribed flow rate (in this example, 0.8 SLM), and then, is supplied constantly, and N₂ is supplied at a constant flow rate of 0.2 SLM. As such, to effectively set the flow rate of SiH₄ to the low flow rate in the pre-purge process, a change rate of the flow rate up to the prescribed flow rate is decreased to improve the surface state of the a-Si film.

The flow rate reaches 0.5 SLM for several seconds in the first embodiment, but, in the current embodiment, the flow rate is decreased by about 1/10 and reaches 0.5 SLM after about 30 seconds. In this manner, the flow rate of SiH₄ in the pre-purge process of SiH₄ can be repeated to an ideal low flow rate state. In a DEPO process (DEPO) denoted by reference numeral 3, the in-furnace pressure is decreased (in this example, from 100 Pa to 40 Pa) for about 30 seconds, and the flow rate of SiH₄ is increased to the prescribed flow rate of 0.8 SLM. Under this condition, the a-Si film is formed.

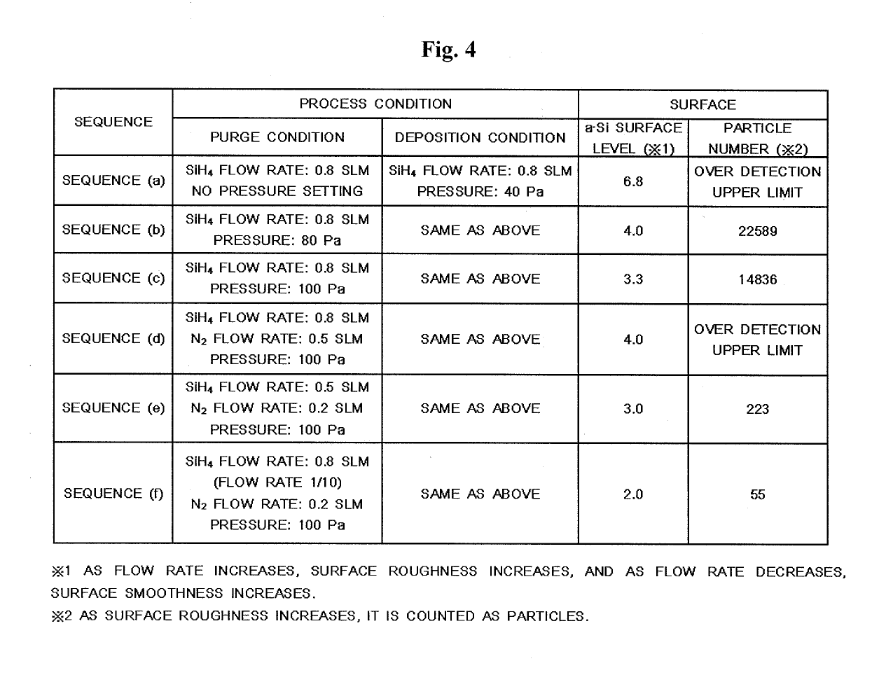

FIG. 4 is a table illustrating evaluation results of the surface roughness of a-Si films.

In all sequences, conditions of DEPO processes are set to a common condition of an SiH₄ flow rate of 0.8 SLM and a pressure of 40 Pa. A sequence (a) of FIG. 4 is a related art sequence, and an SiH₄ flow rate is set to 0.8 SLM and a pressure is not set as a condition of a pre-purge process, and a condition of a DEPO process is the above-described common condition. In this case, according to a measurement result of the surface state of the a-Si film, a surface level was 6.8, and the number of particles could not be measured because of an overflow.

Next, in a sequence (b) of FIG. 4, as a condition of a pre-purge process, compared to the sequence (a), a pressure is set to 80 Pa that is higher than the pressure of a DEPO process, and a condition of the DEPO process is the above-described common condition. In this case, according to a measurement result of the surface state of the a-Si film, a surface level was 4.0, and the number of particles was 22589. That is, it is turned out that the pressure setting for the pre-purge process is effective.

Next, in a sequence (c) of FIG. 4, as a condition of a pre-purge process, compared to the sequence (b), a pressure is set to 100 Pa, and thus, only the pressure condition is changed and a condition of a DEPO process is the above-described common condition. In this case, according to a measurement result of the surface state of the a-Si film, a surface level was 3.3, and the number of particles was 14836. That is, it is turned out that the pressure increase for the pre-purge process is effective.

Next, in a sequence (d) of FIG. 4, as a condition of a pre-purge process, compared to the sequence (c), N₂ is supplied at 0.5 SLM, and a total gas flow rate of SiH₄ and N₂ is set to 1.3 SLM, and a condition of a DEPO process is the above-described common condition. In this case, according to a measurement result of the surface state of the a-Si film, a surface level was degraded to 4.0, and the number of particles was undesirably increased to over the detection upper limit. That is, it is turned out that the surface state of the film is deteriorated when the gas flow rate of the pre-purge process is increased.

Next, in a sequence (e) of FIG. 4, as a condition of a pre-purge process, compared to the sequence (d), SiH₄ is supplied at 0.5 SLM and N₂ is supplied at 0.2 SLM, and a total gas flow rate of SiH₄ and N₂ is maintained at 0.7 SLM so as to decrease the total gas flow rate under an SiH₄ gas flow rate of a DEPO process, and a condition of the DEPO process is the above-described common condition. In this case, according to a measurement result of the surface state of the a-Si film, a surface level was 3.0, and the number of particles was 223. That is, it is turned out that the decreasing of the gas flow rate of the pre-purge process under the gas flow rate of the DEPO process is effective.

Next, in a sequence (f) of FIG. 4, as a condition of a pre-purge process, like the sequence (e), SiH₄ is supplied at 0.5 SLM and N₂ is supplied at 0.2 SLM, and a total gas flow rate of SiH₄ and N₂ is maintained at 0.7 SLM so as to obtain the same total gas flow rate as that of the sequence (e), and the flow rate of SiH₄ is slowly increased up to a prescribed flow rate of 0.5 SLM, and a condition of a DEPO process is the above-described common condition. In this case, according to a measurement result of the surface state of the a-Si film, a surface level was 2.0, and the number of particles was 55. That is, it is turned out that the slow increasing of the gas flow rate of the pre-purge process up to the prescribed flow rate is effective.

From the above-described results, the surface roughness of an a-Si film can be improved by decreasing the flow rate of SiH₄ gas in an initial stage of a film forming process under the flow rate of SiH₄ gas of a post-initial stage. In addition, the surface roughness of an a-Si film can be improved by increasing the inner pressure of a reaction furnace in an initial stage of a film forming process over the inner pressure of the reaction furnace of a post-initial stage. In addition, in an initial stage of a film forming process, by decreasing a change rate of the flow rate of SiH₄ to a set flow rate of SiH₄ (by slowly increasing the flow rate of SiH₄), the surface roughness of an a-Si film can be further improved.

According to another embodiment, the present invention may be applied to a substrate processing apparatus configured to perform a doping process with gas different from SiH₄ to form amorphous silicon. For example, also in the case of B-Dope-poly (SiH₄+BCl₃) or B-PolySiGe (SiH₄+BCl₃+GeH₄), the flow rate thereof is slowly increased as in the manner of supplying SiH₄ gas, so as to obtain the same effect as that of the SiH₄ gas.

According to the present invention, the surface roughness of an a-Si film can be improved, and thus, the a-Si film can have a smoother surface.

(Supplementary Note)

Although the present invention is characterized by the appended claims, the present invention also includes the following embodiments.

(Supplementary Note 1)

According to an embodiment of the present invention, there is provided a method of manufacturing a semiconductor device, the method comprising:

in a process of forming an amorphous silicon film on a substrate,

setting, in an initial stage of the process, an in-furnace pressure to a first pressure to supply SiH₄; and

setting, in a stage after the initial stage, the in-furnace pressure to a second pressure lower than the first pressure to supply SiH₄.

(Supplementary Note 2)

According to another embodiment of the present invention, there is provided a method of manufacturing a semiconductor device, the method comprising:

in a process of forming an amorphous silicon film on a substrate,

supplying, in an initial stage of the process, SiH₄ at a first flow rate; and

supplying, in a stage after the initial stage, SiH₄ at a second flow rate greater than the first flow rate.

(Supplementary Note 3)

According to another embodiment of the present invention, there is provided a method of manufacturing a semiconductor device, the method comprising:

in a process of forming an amorphous silicon film on a substrate,

setting, in an initial stage of the process, an in-furnace pressure to a first pressure to supply SiH₄ at a first flow rate; and

setting, in a stage after the initial stage, the in-furnace pressure to a second pressure lower than the first pressure to supply SiH₄ at a second flow rate greater than the first flow rate.

(Supplementary Note 4)

According to another embodiment of the present invention, there is provided a substrate processing apparatus comprising:

a process furnace;

a monosilane gas supply part configured to supply monosilane gas;

a pressure control part configured to control pressure; and

a controller control part configured to control the monosilane gas supply part to supply the monosilane gas and form an amorphous silicon film at a first pressure in an initial stage of a process of forming the amorphous silicon film on a substrate, the controller control part being configured to control the monosilane gas supply part to form the amorphous silicon film at a second pressure higher than the first pressure after the initial stage, the controller control part being configured to control the pressure control part such that the second pressure is less than the first pressure in the initial stage.

(Supplementary Note 5)

According to another embodiment of the present invention, there is provided a substrate processing apparatus comprising:

a process furnace;

a monosilane gas supply part configured to supply monosilane gas;

a pressure control part configured to control pressure; and

a controller control part configured to control the monosilane gas supply part to supply the monosilane gas and supply the monosilane gas at a first flow rate in an initial stage of a process of forming an amorphous silicon film on a substrate, the controller control part being configured to control the monosilane gas supply part to supply the monosilane gas at a second flow rate greater than the first flow rate after the initial stage.

(Supplementary Note 6)

In the substrate processing apparatus of Supplementary Note 5, when the monosilane gas is supplied at the first and second flow rates, the controller control part may control the monosilane gas supply part to slowly increase a flow rate up to the first and second flow rates.

What is claimed is:

1. A method of manufacturing a semiconductor device, the method comprising:
in a process of forming an amorphous silicon film on a substrate,
setting, in an initial stage of the process, an in-furnace pressure to a first pressure to supply SiH₄; and
setting, in a stage after the initial stage, the in-furnace pressure to a second pressure lower than the first pressure to supply SiH₄.

2. A method of manufacturing a semiconductor device, the method comprising:
in a process of forming an amorphous silicon film on a substrate,
supplying, in an initial stage of the process, SiH₄ at a first flow rate; and
supplying, in a stage after the initial stage, SiH₄ at a second flow rate greater than the first flow rate.

3. A method of manufacturing a semiconductor device, the method comprising:
in a process of forming an amorphous silicon film on a substrate,
setting, in an initial stage of the process, an in-furnace pressure to a first pressure to supply SiH₄ at a first flow rate; and
setting, in a stage after the initial stage, the in-furnace pressure to a second pressure lower than the first pressure to supply SiH₄ at a second flow rate greater than the first flow rate.

4. A substrate processing apparatus comprising:
a process furnace;
a monosilane gas supply part configured to supply monosilane gas;
a pressure control part configured to control pressure; and
a controller control part configured to control the monosilane gas supply part to supply the monosilane gas and form an amorphous silicon film at a first pressure in an initial stage of a process of forming the amorphous silicon film on a substrate, the controller control part being configured to control the monosilane gas supply part to form the amorphous silicon film at a second pressure higher than the first pressure after the initial stage, the controller control part being configured to control the pressure control part such that the second pressure is less than the first pressure in the initial stage.

5. A substrate processing apparatus comprising:
a process furnace;
a monosilane gas supply part configured to supply monosilane gas;
a pressure control part configured to control pressure; and
a controller control part configured to control the monosilane gas supply part to supply the monosilane gas and supply the monosilane gas at a first flow rate in an initial stage of a process of forming an amorphous silicon film on a substrate, the controller control part being configured to control the monosilane gas supply part to supply the monosilane gas at a second flow rate greater than the first flow rate after the initial stage.

6. The substrate processing apparatus of claim 5, wherein, when the monosilane gas is supplied at the first and second flow rates, the controller control part controls the monosilane gas supply part to slowly increase a flow rate up to the first and second flow rates.
